(19) United States
(12) Patent Application Publication
(10) Pub. No.: US 2008/0080226 A1
(43) Pub. Date: Apr. 3, 2008

(54) Memory system and method of operating the memory system

(76) Inventors: Thomas Mikolajick, Dresden (DE); Rainer Spielberg, Kirchheim (DE); Nicolas Nagel, Dresden (DE); Michael Specht, Muenchen (DE); Josef Willer, Riemerling (DE); Detlev Richter, Muenchen (DE); Luca de Ambroggi, Munchen (DE); Andreas Taeuber, Unterschleissheim (DE)

Correspondence Address: SLATER & MATSIL LLP, 17950 PRESTON ROAD, SUITE 1000, DALLAS, TX, 75252, US

(21) Appl. No.: 11/526,850

(22) Filed: Sep. 25, 2006

(51) Int. Cl. G11C 11/00; G11C 5/14

(52) U.S. Cl. 365/148; 365/228

(57) ABSTRACT

A memory system includes a plurality of resistive memory cell fields including at least a first resistive memory cell field and a second resistive memory cell field, the first resistive memory cell field formed with a plurality of resistive memory cells storing data at a first data storage speed, the second resistive memory cell field formed with a plurality of resistive memory cells storing data at a second data storage speed lower than the first data storage speed, and a controller controlling data transfer between the plurality of resistive memory cell fields.

### TECHNICAL FIELD

The present invention relates, in general,to a memory system and to a method of operating the memory system.

### BACKGROUND

A conventional memory system includes a plurality of non-volatile or volatile memory cells to store data. It is desirable to provide a storage capacity as high as possible to the user in order to store a large amount of data in the memory system. Furthermore, the writing and reading of the data into the memory system and from the memory system, respectively, should be as fast as possible in order to provide a high user acceptance of the memory system.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1A is a schematic diagram of a portion of a resistive memory cell field constructed using a transistor architecture;

FIG. 1B is a schematic diagram of a portion of a resistive memory cell field constructed using a diode architecture;

FIG. 1C is a schematic diagram of a portion of a resistive memory cell field constructed using a cross-point architecture;

FIG. 2 is a block diagram of a first embodiment of a memory system including a plurality of resistive memory fields;

FIG. 3 is a schematic diagram of a second embodiment of a memory system including a plurality of resistive memory fields;

FIG. 4 is a schematic diagram of a third embodiment of a memory system including a plurality of resistive memory fields;

FIG. 5 is a schematic diagram of a fourth embodiment of a memory system including a plurality of resistive memory fields;

FIG. 6A is a schematic diagram showing an example of a plurality of resistive memory fields implemented on a single chip;

FIG. 6B is a schematic diagram showing an example of a plurality of resistive memory fields implemented on a plurality of chips;

7A is a diagram of the first memory of the memory system of FIG. 4 illustrating the data partitioning in accordance with one embodiment of the invention; and

FIG. 7B is a diagram of the memories of the memory system of FIG. 5 illustrating the data partitioning in accordance with one embodiment of the invention.

### DETAILED DESCRIPTION OF ILLUSTRATIVE EMBODIMENTS

As used herein the terms connected and coupled are intended to include both direct and indirect connection and coupling, respectively. The terms “directly connected” and “directly coupled” are used to connote connection or coupling without any intermediate components.

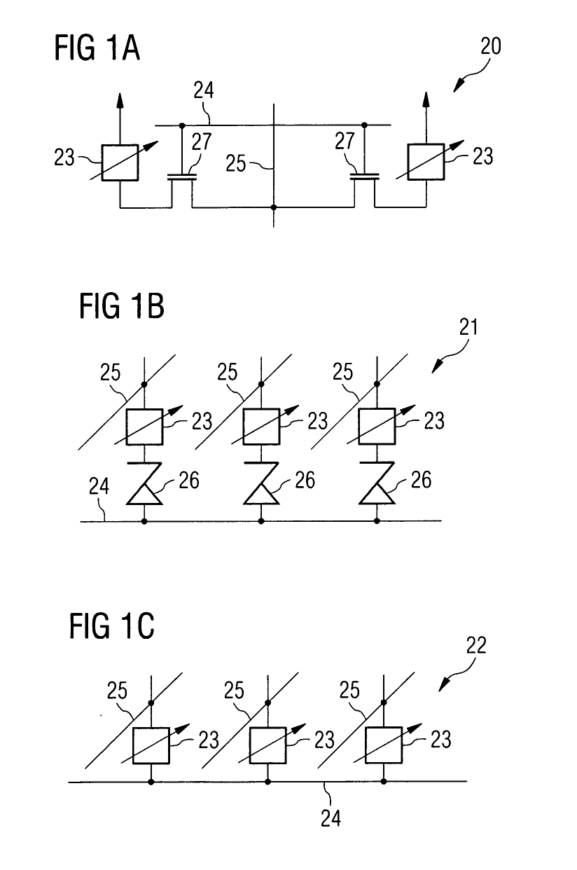

FIGS. 1A, 1B, and 1C show some examples of memory cell field architectures that can be used to practice the invention. FIG. 1A shows a portion of a resistive memory cell field 20 constructed with a transistor architecture enabling a very fast access time. Each storage cell is formed from a resistive memory cell, such as, for example, a reconfigurable conductive filament storage element 23 and a select element 27. The select element 27, for example, a transistor, is used for selecting the reconfigurable conductive filament storage element 23. When an appropriate signal is applied to a wordline 24, the select element 27 connects the reconfigurable conductive filament storage element 23 to a bitline 25.

The reconfigurable conductive filament storage element 23 can be electrically configured and reconfigured to be in a state in which a conductive filament is formed between two terminals or to alternatively be in a state in which the conductive filament no longer exists. In some cases, the conductive filament can be formed to a greater or lesser degree allowing for multilevel storage. The conductive filament can be formed within an insulating material, e.g., a suitable electrolyte material. The conductive filament can be formed in the entire volume of the insulating material or in a portion of the insulating material. The electrical configuration of selectively constructing and removing the conductive filament can be repeated many times depending upon the endurance of the reconfigurable conductive filament storage element 23. The reconfigurable conductive filament storage element 23 could be constructed using a suitable electrolytic material, for example, GeS, GeSe, WOx, or CuS, and using suitable ions, for example, Cu+ or Ag+ for forming the reconfigurable conductive filament. The inert electrode could be formed from a suitable metal, for example, W. One example of a well-known reconfigurable conductive filament storage element 23 is a programmable metallization cell (PMC) (also referred to as a Conductive Bridging Random Access Memory, CBRAM), however, other reconfigurable devices may also be used with the present invention, e.g., other reconfigurable devices that have a similar behavior, e.g., other reconfigurable multi bit cells.

Different operational modes can be obtained by programming the reconfigurable conductive filament storage element 23 using different current densities. When storing a single bit, there are basically two operational modes that are useful. When the reconfigurable conductive filament storage element 23 is programmed using a first current density, e.g., a higher current density, as is normally the case when it is being used for non-volatile storage of data, the reconfigurable conductive filament storage element 23 will have a longer data retention time, which is in the order of about ten years, and a lower endurance in the order of about 106 to 109 cycles. When the reconfigurable conductive filament storage element 23 is programmed using a second current density, e.g., current density that is lower than the first current density, the reconfigurable conductive filament storage element 23 will have a shorter data retention time, which is in the range of a few hours or possibly even a few days. Advantageously, however, the endurance of the conductive filament storage element 23 is greatly increased when programmed using a lower current density and can be for example, in the order of 1016 cycles.

In general, in the context of this description, “different operational modes” for operating the memory cell fields may be understood to be different types of programming or reading the memory cells of the different memory cell fields, e.g., using different programming or reading voltages or different programming or reading currents for the memory cells of the different memory cell fields.

In the context of this description, a “volatile memory cell” may be understood as memory cell storing data, the data being refreshed during a power supply voltage of the memory system being active, in other words, in a state of the memory system, in which it is provided with power supply voltage. In contrast thereto, a “non-volatile memory cell” may be understood as memory cell storing data, wherein the stored data is/are not refreshed during the power supply voltage of the memory system being active. However, a “non-volatile memory cell” in the context of this description includes a memory cell, the stored data of which may be refreshed after an interruption of the external power supply. As an example, the stored data may be refreshed during a boot process of the memory system after the memory system had been switched off or had been transferred to an energy deactivation mode for saving energy, in which mode at least some or most of the memory system components are deactivated. Furthermore, the stored data may be refreshed on a regular timely basis, but not, as with a “volatile memory cell” every few picoseconds or nanoseconds or milliseconds, but rather in a range of hours, days, weeks, or months.

FIG. 1B shows a portion of a resistive memory cell field 21 constructed with a diode architecture. The diode architecture provides a higher storage density than the transistor architecture and still provides a relatively fast access time. Each storage cell in the resistive memory cell field 21 is formed from a Zener diode 26 connected in series with the reconfigurable conductive filament storage element 23. The Zener diode 26 and the reconfigurable conductive filament storage element 23 are connected between the bitline 25 and the wordline 24. In an alternative embodiment of the invention, any other component that has a similar characteristic as the Zener diode 26 may be used instead of the Zener diode 26, e.g., a component that has a normal diode characteristic in conducting direction and that suddenly becomes low ohmic in reverse-biasing direction when a predefined breakthrough voltage is reached.

FIG. 1C shows a portion of a resistive memory cell field 22 constructed using a cross-point architecture. Each storage cell in the resistive memory cell field 22 is formed from the reconfigurable conductive filament storage element 23 connected between the bitline 25 and the wordline 24. A higher storage density can usually be obtained with the cross-point architecture than with the transistor or diode architectures. The access time, however, is typically slower.

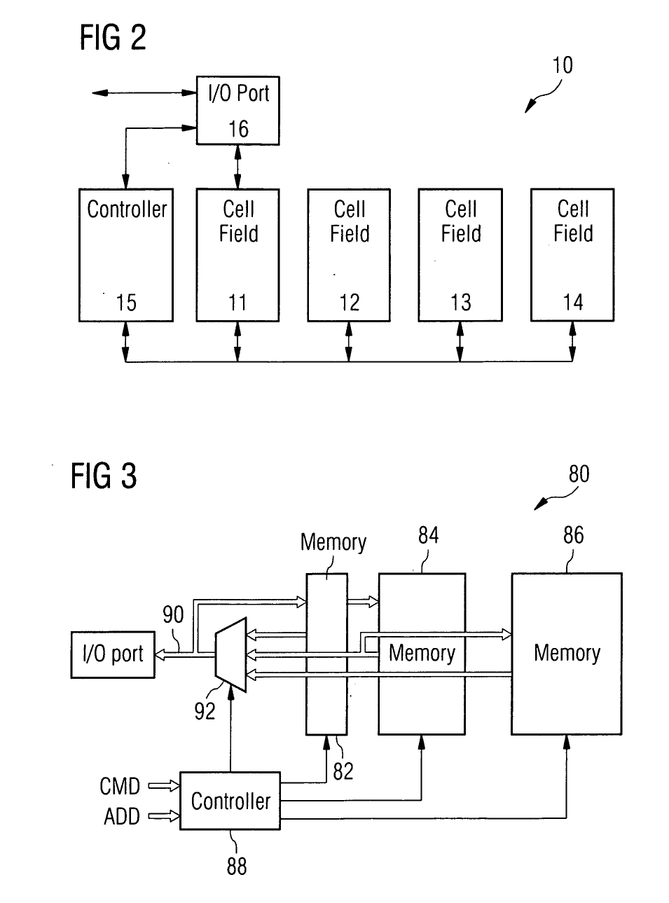

The invention is based on providing a memory system with a fast access time and a high storage density and with at least some non-volatile resistive memory fields. FIG. 2 is a block diagram of a first embodiment of a memory system 10 including resistive memory cell means, specifically, a plurality of resistive memory cell fields 11-14. The memory system 10 also includes control means, specifically, a controller 15 constructed for controlling data transfer between the plurality of resistive memory cell fields 11-14 and an I/O port 16 and/or bus. The resistive memory cell fields 11-14 are fully functional and include all necessary read, program, and erase circuitry. Four resistive memory cell fields 11-14 are shown in this example, however, the invention could be implemented with more resistive memory cell fields or with as few as two resistive memory cell fields 11-12. The resistive memory cell field 11 is constructed to serve as an input/output (I/O) cell field enabling communication between external devices such as, for example, microcontrollers and microprocessors (not shown) connected to the I/O port 16 and the plurality of resistive memory cell fields 11-14. Hereinafter, reference numeral 11 will be used when referring to the I/O cell field 11. The transfer of data between the I/O cell field 11 and one or more other resistive memory fields 12-14 will be explained in detail further below. It is desirable to construct the I/O cell field 11 to have a very fast access time since it enables the transfer of data between external devices and the memory system 10. The I/O cell field 11 should also have a sufficiently large endurance since it will be read from and written to frequently. The access time and the endurance of the I/O cell field 11 can be suitably optimized by selecting an appropriate architecture for the I/O cell field 11 and/or by appropriately controlling the operating conditions or operational mode of the resistive memory cells in the I/O cell field 11.

The I/O cell field 11 may be constructed using the transistor architecture shown in FIG. 1A, which enables a fast access time. By using the operational mode with the lower current density, the I/O cell field 11 may have an endurance in the order of 1016 cycles, which is sufficient. Since in this case, the I/O cell field 11 is volatile, it can be refreshed when necessary. It should be understood that constructing the I/O cell field 11 using the architecture shown in FIG. 1A and using the low current operational mode just described is just one possible example of a suitable design.

The second resistive memory cell field 12 is e.g., constructed to be non-volatile. This can be achieved, for example, by programming the second resistive memory cell field 12 using the higher programming current. The second resistive memory cell field 12 can be constructed to have a greater storage density than the I/O cell field 11, and can be constructed to have a relatively fast access time. By greater storage density, it is meant that the second resistive memory cell field 12 could store a greater amount of data bits per volume than the I/O cell field 11. One possibility for satisfying this condition is to construct the second resistive memory cell field 12 using the diode architecture shown in FIG. 1B. The storage density of the second resistive memory cell field 12 can be further increased by using multilevel storage (in other words, using storage of a plurality of data bits per memory cell) and/or by using a specific architecture, for example, using the cross-point architecture.

The third resistive memory cell field 13, the fourth resistive memory cell field 14, and any additional resistive memory cell fields may be constructed to be non-volatile and can be constructed to have a storage density that is as high as possible. These fields can be constructed using either the diode architecture shown in FIG. 1B or the cross-point architecture shown in FIG. 1C. As already stated, another option that may be additionally or alternatively used for increasing the storage density, or the amount of data bits stored per volume, is using multilevel storage.

In the first exemplary embodiment, the controller 15 is constructed to initially store data that is coming into the memory system from an external device via the I/O port 16, in the I/O cell field 11. The controller 15 will then copy the data from the I/O cell field 11 into the second resistive memory cell field 12 depending on predefined conditions, when e.g., either one of two conditions are fulfilled: a) when the I/O cell field 11 is filled with data beyond a predetermined threshold; or b) when a predetermined amount of data has not been accessed for a predetermined amount of time. When a predetermined criterion is fulfilled, e.g., when the I/O cell field 11 is filled with data up to or beyond a predetermined threshold, a predetermined amount of data that has not been accessed for the longest amount of time will be copied into the second resistive memory cell field 12. The controller 15 is constructed to analogously copy data from the second resistive memory cell field 12 into the third resistive memory cell field 13 each time a predetermined amount of the storage capacity of the second resistive memory cell field 12 has been met or exceeded. This copying of data from an nth resistive memory cell field into the (n+1)th resistive memory cell field is performed in the background, e.g., non-observable for the user, each time a predetermined amount of the storage capacity of the nth resistive memory cell field has been met or exceeded. It should be mentioned that in alternative embodiments of the invention, other conditions and other criteria than those mentioned above may be provided.

In this first exemplary embodiment, when reading from the memory system 10, data will consecutively be copied from an (n+1)th resistive memory cell field into the nth resistive memory cell field until the requested data is available in the I/O cell field 11. For example, if the requested data is in the third resistive memory cell field 13, the data will be copied to the second resistive memory cell field 12 and then from the second resistive memory cell field 12 into the I/O cell field 11 so that the data is available for memory system external output. In other embodiments described later, data is read from each cell field without having to be copied into other cell fields first via e.g., one or more additional connections between the I/O cell field 11 and the respective other cell field.

Since the I/O cell field 11 is a volatile memory field, the controller 15 will copy the data from the I/O cell field 11 into the second resistive memory cell field 12 upon the occurrence of a further condition, namely, when the memory system 10 is switched off or suffers from an unintentional power loss or an unintentional power off. If there is not enough space available in the second resistive memory cell field 12 for storing the data from the I/O cell field 11, then space will be provided by copying either all of the data in the second resistive memory cell field 12 or at least an amount of data from the second resistive memory cell field 12 into the third resistive memory cell field 13 sufficient to provide enough space for storing the data from the I/O cell field 11. When the memory system 10 is switched back on or when power is restored, the controller 15 will copy the data from the second resistive memory cell field 12 back into the I/O cell field 11. In an alternative embodiment of the invention, the controller 15 will copy the data from the I/O cell field 11 into the second resistive memory cell field 12 on a regular timely basis, in other words, in each case after a predetermined time period after a previous copy process.

Another feature that may be implemented is to mark certain units of data, for example, a block of data, such that the data will always be available in the I/O cell field 11 when the memory system 10 is switched on. One way of implementing this feature is by associating a respective data word with each unit of data, and using this data word to indicate whether the unit of data will be permanently stored in the I/O cell field 11 when the memory system 10 is switched on. It is also possible to use the data word to indicate how many access cycles have passed since the associated unit of data has been read or moved, and in this case the controller 10 can use the data word for determining when the associated unit of data should be copied from an (n+1)th resistive memory cell field into the nth resistive memory cell field, as was described above with regard to condition b.

In an alternative embodiment of the invention, the data could be copied from an (n+1)th resistive memory cell field into an (n-m)th resistive memory cell field, with m being an integer number. In other words, one or more resistive memory cell fields may be skipped in a copy process.

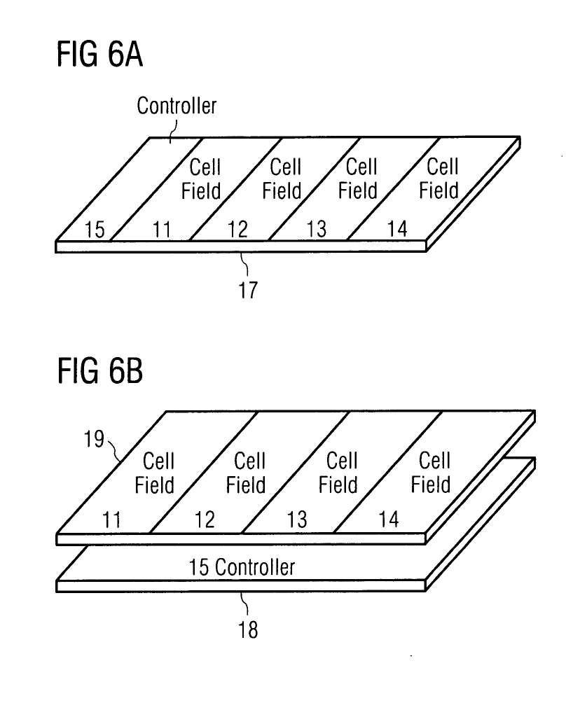

FIG. 6A is a schematic diagram showing an example of implementing the plurality of resistive memory cell fields 11-14 and the controller 15 on a single chip 17. FIG. 6B is a schematic diagram of another example showing the plurality of resistive memory cell fields 11-14 and the controller 15 implemented on a plurality of chips 18, 19 that are vertically stacked, although they could be horizontally spaced instead. The required horizontal area can be further minimized by vertically stacking several resistive memory cell fields. For example, although not shown, each of the resistive memory cell fields 13 and 14 could be constructed on a separate chip and the chips could be vertically stacked on a chip containing resistive memory cell fields 11 and 12 and on another chip containing the controller 15. The controller 15 need not necessarily be implemented in the same package as the plurality of resistive memory cell fields 11-14.

FIG. 3 is a block diagram showing an example of a second embodiment of a memory system 80 including a plurality of non-volatile resistive memory cell fields 82, 84, 86 and a controller 88 for controlling data transfer between the plurality of resistive memory cell fields 82, 84, 86 and an input/output (I/O) port 90 or bus. The 1/O port 90 connects the memory system 80 to external components (not shown). Many different types of storage elements could be selected to form the resistive memory cell fields 82, 84, 86. As one example, the resistive memory cell fields 82, 84, 86 could be formed from resistive memory elements, for example, programmable metallization cells (PMC) or as another example, phase change memory elements. Not all of the resistive memory cell fields 82, 84, 86 need to be constructed using the same type of memory elements that are used in other resistive memory cell fields. Some or all of the resistive memory cell fields 82, 84, 86 can be multilevel resistive memory cell fields.

A controller 88 writes data into the plurality of resistive memory cell fields 82, 84, 86 of the memory system in a serial manner. In an alternative embodiment of the invention, the data may be written into the plurality of resistive memory cell fields 82, 84, 86 of the memory system in a parallel manner. For example, incoming data is first written from an I/O port 90 to the first resistive memory cell field 82. When the amount of data being stored in the first resistive memory cell field 82 reaches a predetermined threshold or when another predefined criterion is fulfilled, at least some and perhaps all of the data stored in the first resistive memory cell field 82 is copied from the first resistive memory cell field 82 into the second resistive memory cell field 84. This predetermined threshold could be when the first resistive memory cell field 82 is close to being full, is completely full, or some other desired value. When the amount of data being stored in the second resistive memory cell field 84 reaches a predetermined threshold, at least some and perhaps all of the data stored in the second resistive memory cell field 84 is written into the third resistive memory cell field 86. If additional resistive memory cell fields are implemented, this sequential procedure can be continued until the last memory is reached. In an alternative embodiment of the invention, the data is written into the plurality of resistive memory cell fields 82, 84, 86 of the memory system in a parallel manner. In this case, a detection unit may be provided that detects, when the amount of data to be stored in the first resistive memory cell field 82 reaches a predetermined threshold or when another predefined criterion is fulfilled and, if this is the case, starts writing the exceeding data into one or more other resistive memory cell fields 84, 86. In another embodiment of the invention, depending on the rate the data should be stored, the data may be directly stored into the resistive memory cell field 86, for example.

Some or all of the resistive memory cell fields 82, 84, 86 can have different storage capacities. Each memory cell field 82, 84, 86 that is further down the line in the writing sequence can have, for example, a storage density that is greater than that of the previous memory. For example, the second resistive memory cell field 84 can be constructed with a larger storage density than the first resistive memory cell field 82, the third resistive memory cell field 86 can be constructed with a larger storage density than the second resistive memory cell field 84, and if additional resistive memory cell fields are present, the storage density can be continually increased for each additional level. The storage density can be increased, for example, by increasing the density of the storage elements and/or the number of storage levels of the storage elements. In this example, the second resistive memory cell field 84 is a 2-level non-volatile memory (NVM) and the third resistive memory cell field 86 is a 4-level non-volatile memory (NVM). The third resistive memory cell field 86 could be constructed with an even higher number of levels if desired. Any of the resistive memory cell fields 82, 84, 86 can be formed using any one of many known architectures and may be formed, for example, from multiple arrays. Any of the resistive memory cell fields 82, 84, 86 may even include multiple resistive memory cell fields.

Some or all of the resistive memory cell fields 82, 84, 86 can have different access speeds. The term different data bandwidths is intended to mean that the resistive memory cell fields 82, 84, 86 have different write speeds when being written to and analogously have different read speeds when being read from and therefore provide different input/output timing behavior at the input/output interface of the respective memory cell fields 82, 84, 86. For example, if the second resistive memory cell field 84 is constructed as a 2-level non-volatile memory and the third resistive memory cell field 86 is constructed as a 4-level non-volatile memory, it will take longer to write to the third resistive memory cell field 86 than to the second resistive memory cell field 84 because of the greater complexity of the third resistive memory cell field 86. Analogously, it will take longer to read from the third resistive memory cell field 86.

There is a direct data output path from each of the resistive memory cell fields 82, 84, 86 to a multiplexer 92. When the command signals applied to the command lines CMD indicate that a read is to be performed, the controller 88 reads data from a particular one of the plurality of resistive memory cell fields 82, 84, 86 of the memory system depending on the address signals applied to the address lines ADD going to the controller 88. The controller 88 appropriately controls the multiplexer 92 to place the data read from the appropriate one of the resistive memory cell fields 82, 84, 86 to the I/O port 90. Since the read speed of some or all of the resistive memory cell fields 82, 84, 86 is different, the time required to output the desired data will depend upon which one of the resistive memory cell fields 82, 84, 86 is read. For example, suppose that the first resistive memory cell field 82 has the fastest read speed, the second resistive memory cell field 84 has a slower read speed, and the third resistive memory cell field 86 has an even slower read speed. In this case, for example, it will take longer to obtain data stored in the third resistive memory cell field 86 than it takes to obtain data stored in the second resistive memory cell field 84.

The term, “unit of data”, can be defined, for example, as a collection of data of a predefined size, for example a block of a certain size. In one embodiment of the invention, the controller 88 manages the data so that a group of the most recently accessed units of data are stored in the first resistive memory cell field 82, which has the fastest read speed, a group of the next most recently used units of data are stored in the second resistive memory cell field 84, which has the next fastest read speed, and a group of units of data accessed the longest time ago are stored in the third resistive memory cell field 86, which has the slowest read speed. Whenever the time period since a respective unit of data has been last accessed exceeds a predetermined time period or number of access cycles, or in case another predefined criterion is fulfilled, the respective unit of data will be copied into the memory that is next in the serial input chain. This next memory will likely have a read speed that is slower than the read speed of the memory in which the unit of data is presently stored. For example, whenever the time period since a respective unit of data in the second resistive memory cell field 84 has been last accessed exceeds a predetermined time period or number of access cycles, or in case another predefined criterion is fulfilled, the respective unit of data will be copied into the third resistive memory cell field 86. By using this procedure, the controller 88 insures that more recently accessed data will be available in a shorter time period than data that has not been accessed as recently. In alternative embodiments of the invention, other data storage strategies (in other words, other data writing and/or data reading strategies) may be provided.

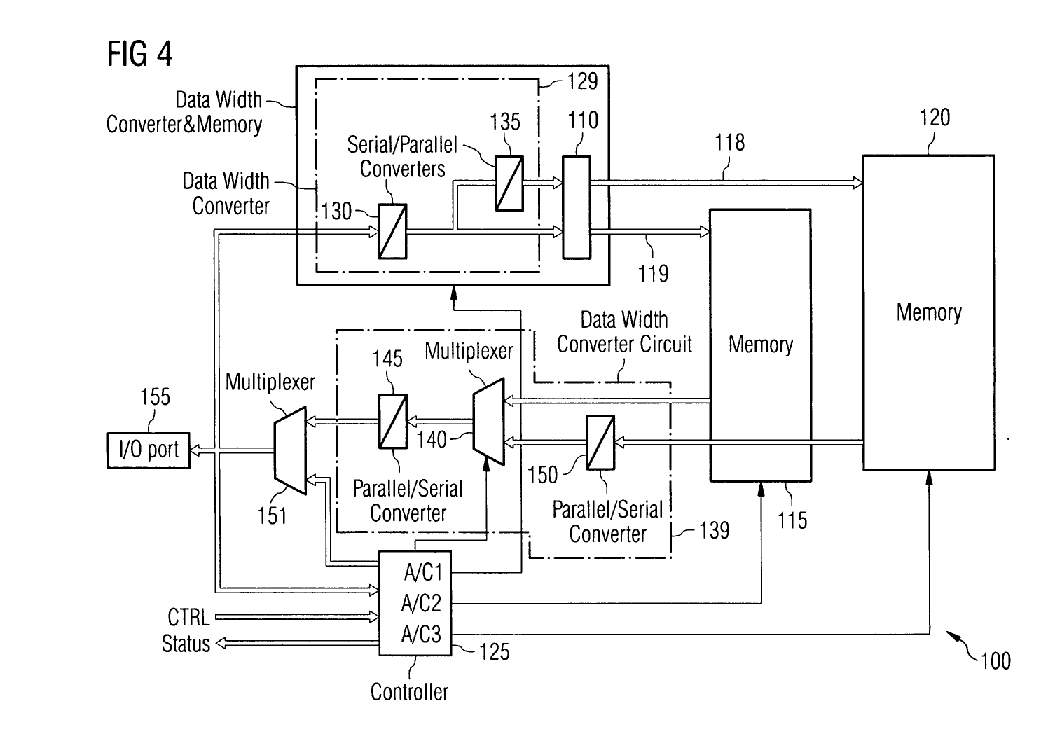

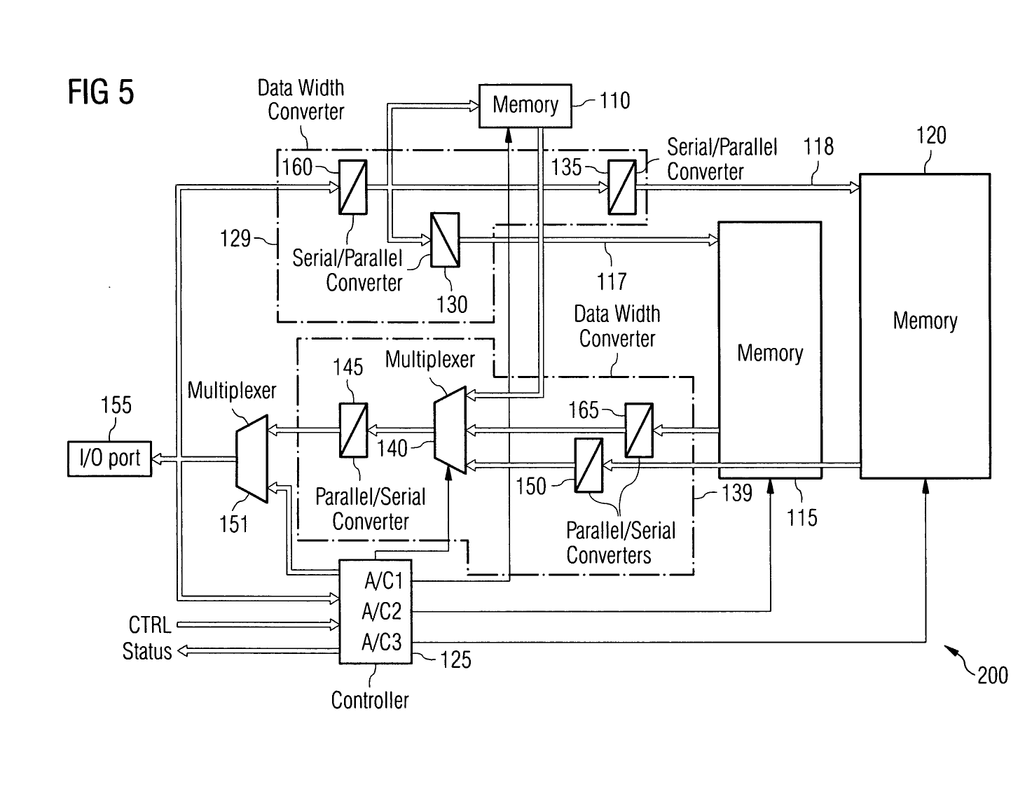

FIG. 4 is a block diagram showing an example of a third embodiment of a memory system 100 including a plurality of resistive memory cell fields 110, 115, and 120 and control means, for example, a controller 125. The controller 125 has address and control lines A/C1, A/C2, and A/C3 for controlling the plurality of resistive memory cell fields 110, 115, and 120. In this example, only the first resistive memory cell field 110, the second resistive memory cell field 115, and the third resistive memory cell field 120 are shown, however, additional resistive memory cell fields could be implemented. There are different possibilities for utilizing the first resistive memory cell field 110. In this example, the first resistive memory cell field 110 is again constructed as a volatile memory cell field, for example, using the transistor architecture and the lower density programming current. All of the other resistive memory cell fields 115, 120 (and additional resistive memory cell fields, if provided) are constructed as non-volatile resistive memory cell fields similar to the manner described with regard to the first embodiment. Some or all of the other resistive memory cell fields 115, 120 can be multilevel resistive memory cell fields. The resistive memory cell fields 115, 120 can use any of a number of memory designs and architectures, and may be formed, for example, from multiple arrays. Each of the resistive memory cell fields 115, 120 could also include multiple resistive memory cell fields.

This embodiment is based on writing data to different resistive memory cell fields 115, 120 of the memory system 100 by increasing the data bus width and thereby reducing the data transfer rate or data rate of the incoming data to account for the different write speeds of the resistive memory cell fields 115, 120. Analogously, when the resistive memory cell fields 115, 120 are read, the data bus width is decreased, thereby increasing the data rate of the read data to account for the different read speeds of the resistive memory cell fields 115, 120. In this manner, the data bandwidth provided at the I/O means or I/O port 155 remains constant throughout the entire memory system 100 and the write speed differences and read speed differences of the resistive memory cell fields 115, 120 are hidden from a view externally from the memory system 100.

For example, when reading from the memory system, the data bandwidth of each one of the resistive memory cell fields 115, 120 can be set to the data bandwidth of the I/O means or I/O port 155. Since a particular memory, say the third resistive memory cell field 120, for example, is not being read at the speed of operation of the I/O port 155, the data bus width at the third resistive memory cell field 120 is set to be greater than the data bus width at the I/O port 155 by an appropriate factor such that the data bandwidth at the third resistive memory cell field 120 equals the data bandwidth of the I/O port 155.

A unit of data, for example, a block, being stored in the memory system 100 can be divided into two portions in which a first portion is stored in the second resistive memory cell field 115 and a second portion is stored in the third resistive memory cell field 120. The memory system 100 can be constructed such that the third resistive memory cell field 120 having a slower speed does not delay the outputting of any portions of the unit of data. Data from the slower third resistive memory cell field 120 can be read and collected while data from the faster second resistive memory cell field 115 is being read and output. After the first portion of the unit of data is output from the faster second resistive memory cell field 115, the second portion of the data from the slower third resistive memory cell field 120 is immediately available for output.

In one embodiment of the invention, the data bandwidths (read speeds and/or write speeds) or equivalently access times of the resistive memory cell fields 110, 115, 120 might be different because the storage densities are different and the number of bits being stored in one memory cell being managed is different or due to other parameters. The second resistive memory cell field 115 is non-volatile and has a medium access time and medium storage density, and the third resistive memory cell field 120 is non-volatile and has a higher storage density and a longer access time (slower speed). In an alternative embodiment of the invention, the second resistive memory cell field 115 is volatile. Furthermore, in yet another embodiment of the invention, the third resistive memory cell field 120 is volatile as well.

The third embodiment of the memory system 100 is designed to compensate for the different write times or speeds of the resistive memory cell fields 115, and 120 by advantageously using data bus width converter means, for example, a data bus width converter circuit 129 including a first serial to parallel converter 130 and a second serial to parallel converter 135. The data bus width converter circuit 129 splits the incoming unit of data, which could be a block, into a plurality of portions, in this example, two portions. The serial to parallel converters 130, 135 are e.g., constructed from a chain of shift registers with a single input and a plurality of parallel outputs providing data after the input data has been shifted in. Each serial to parallel converter 130, 135 reduces the data rate of the incoming data by increasing the data bus width and thereby increasing the parallelism. The data rate reduction required by the first serial to parallel converter 130 depends on the write time or write speed of the second resistive memory cell field 115. The data rate reduction required by the second serial to parallel converter 135 depends on the write time or write speed of the third resistive memory cell field 120 and on the reduction in the incoming data rate that has already been provided by the first serial to parallel converter 130. If additional resistive memory cell fields are implemented, then the data bus width converter circuit 129 can include an additional serial to parallel converter for each additional memory assuming that the write time of the additional memory is longer than that of the previous memory. The page width required to efficiently use each memory is calculated using a ratio between the write speed of the respective memory and the data rate of the input data.

For example, if the data bus width coming into the I/O port 155 is 1 byte, the first serial to parallel converter 130 could increase the data bus width to a size of 8 bytes, thereby reducing the data rate of the data being input to the second resistive memory cell field 115 by a factor of 8. Likewise, the second serial to parallel converter 135 could increase the data bus width by another factor of 4 to obtain a data bus width of 32 bytes and to reduce the data rate of the data being input to the third resistive memory cell field 120 by another factor of 4. In this manner, the input data rate of the incoming data can be adjusted to account for the different write times or write speeds of the different resistive memory cell fields 115, 120. The write times or write speeds might be e.g., different because the storage densities of the resistive memory cell fields 115, 120 are different and the number of bits being stored in one memory cell being managed is different. The factors have merely been provided to explain the process and the exact factors will depend on the write times or write speeds of the respective resistive memory cell fields.

When writing to the memory system 100, both resistive memory cell fields 115, 120 are written. The earliest data coming in from the I/O port 155 goes into the faster part of the memory system 100 and the later data coming in from the I/O port 155 is collected and put in the slower part of the memory system 100. For example, if a unit of data, a data block in this example, of a size of 512 bytes is coming into the memory system 100, the data bus width converter circuit 129 could split the data block into a 2 byte portion and a 500 byte portion. The first 12 bytes could be written into the second resistive memory cell field 115 and the remaining 500 bytes could be written into the third resistive memory cell field 120. These numbers are provided merely to explain the principle. The first resistive memory cell field 110 acts as a buffer so that as soon as 12 bytes are collected in the first resistive memory cell field 110, a write operation is triggered to write the collected data to the second resistive memory cell field 115 using a data bus 117. Then as soon as the remaining 500 bytes are collected in the first resistive memory cell field 110, a write operation is triggered to write the collected data to the third resistive memory cell field 120 using a data bus 118 (see also FIG. 5).

The controller 125 receives control signals from a control signal path CTRL and can provide status data on a status signal path STATUS. The controller 125 has status registers that receive data from the I/O port 155. The controller 125 can also output status data to the I/O port 155.

The memory system 100 includes a first multiplexer 140 such that the controller 125 can select either the data being read from the second resistive memory cell field 115 or the data being read from the third resistive memory cell field 120 for output on the I/O port 155. The memory system 100 includes a second multiplexer 151 such that the controller 125 can select either the data being output from the first multiplexer 140 or status data from the controller 125 for output on the I/O port 155. This feature enables the memory system 100 to be compliant with an interface standard for HDD (hard disk drives), for example, the ATA (advanced technology attachment) standard or the SCSI (Small Computer System Interface) standard. By being compliant with a suitable interface standard, the memory system 100 could be used as a substitute for a hard disk drive, if desired.

Reading the memory system 100 will now be described. The memory system 100 includes another data bus width converter means, for example, a data bus width converter circuit 139 that acts to decrease the data bus width and to increase the data rate of the data being read from the resistive memory cell fields 115, 120.

The data bus width converter circuit 139 includes a first parallel to serial converter 145 (in an alternative embodiment of the invention, a first parallel to parallel converter) to decrease the data bus width and increase the data rate of the data being read from the second resistive memory cell field 115. The first parallel to serial converter 145 performs the inverse operation of that performed by the first serial to parallel converter 130. Considering the example given when discussing the first serial to parallel converter 130, it is seen that the first parallel to serial converter 145 would decrease the data bus width from a size of 8 bytes to a size of 1 byte, thereby increasing the data rate of the data being output from the second resistive memory cell field 115 by a factor of 8 and matching the data rate to that of the I/O port 155.

The data bus width converter circuit 139 includes a second parallel to serial converter 150 (in an alternative embodiment of the invention, a second parallel to parallel converter) to decrease the data bus width and increase the data rate of the data being read from the third resistive memory cell field 120. The second parallel to serial converter 150 performs the inverse operation of that performed by the second serial to parallel converter 135. Considering the example given when discussing the second serial to parallel converter 135, it is seen that the second parallel to serial converter 150 would decrease the data bus width from a size of 32 bytes to a size of 8 bytes, thereby increasing the data rate of the data being output from the third resistive memory cell field 120 by a factor of 4. The data being output from the third resistive memory cell field 120 is also converted by the first parallel to serial converter 145 so that the data bus width is decreased further from a size of 8 bytes to a size of 1 byte, thereby further increasing the data rate of the data being output from the third resistive memory cell field 120 by a factor of 8 and matching the data rate to that of the I/O port 155.

Let us again consider the example given above where a data block of a size of 512 bytes has been stored in the memory system 100. The first 12 bytes have been stored in the second resistive memory cell field 115 and the remaining 500 bytes have been stored in the third resistive memory cell field 120. To read from the memory system 100, the controller 125 concurrently accesses the second resistive memory cell field 115 and the third resistive memory cell field 120. The first 12 bytes are read from the second resistive memory cell field 115, are converted by the first parallel to serial converter 145, and are output on the I/O port 155. At the same time, the remaining 500 bytes are read from the third resistive memory cell field 120 and are converted by the second parallel to serial converter 150. After the first 12 bytes have been output, the remaining 500 bytes are transferred from the first parallel to serial converter 145 to the I/O port 155 for output. In this way, some or preferably all of the time required to read the slower third resistive memory cell field 120 occurs concurrently with the outputting of the data from the second resistive memory cell field 115 so that either a much smaller delay or preferably no delay occurs at all between outputting the data read from the second resistive memory cell field 115 and outputting the data read from the third resistive memory cell field 120.

FIG. 5 is a schematic diagram showing an example of a fourth embodiment of a memory system 200. Portions of the memory system 200 functioning similar to those shown in FIG. 2 are identified using the same reference numerals and will not be described again. In this embodiment, the unit of data, for example, a data block being stored is divided into three portions instead of just two portions as was the case in the third embodiment. In this embodiment, the first resistive memory cell field 110 is not constructed to act as a write buffer, but rather the first resistive memory cell field 110 is constructed as a non-volatile memory and is used to store a first portion of a data block. A second portion of the data block is stored in the second resistive memory cell field 115 and a third portion of the data block is stored in the third resistive memory cell field 120. Notice that the data bus 117 is now also connected to the first multiplexer 140 so that the first multiplexer 140 can apply the first portion of the data block that is read from the first resistive memory cell field 110 to the first serial to parallel converter 145.

If necessary, the data bus width converter 129 can include a third serial to parallel converter 160 to receive incoming data from the I/O port 155 and to increase the data bus width and reduce the data rate of the incoming data from the I/O port 155. In this example, the third serial to parallel converter 160 will be the only serial to parallel converter acting on the first portion of the data block being stored in the first resistive memory cell field 110. The first serial to parallel converter 130 and the second serial to parallel converter 135 are constructed to cooperate with the third serial to parallel converter 160 so that each memory cell field 115, 120 obtains data (a respective portion of the data block) having the proper data bus width and data rate for storage therein via the data buses 117, 118, respectively.

Likewise, the data bus width converter 139 can include a third parallel to serial converter 165 to appropriately change the data bus width and data rate of the second portion of the data block being read from the second resistive memory cell field 115. The first parallel to serial converter 145 is constructed to operate on the data (a respective portion of the data block) read from all of the resistive memory cell fields 110, 115, and 120 so that all portions of the data block output on the I/O port 155 have the proper data bus width and data rate. As an alternative configuration, the output from the second parallel to serial converter 150 could be multiplexed into the input of the third parallel to serial converter 165 so that the third portion of the data block being read from the third resistive memory cell field 120 would pass through all three parallel to serial converters 165, 150, and 145, although this option is not shown in the drawings.

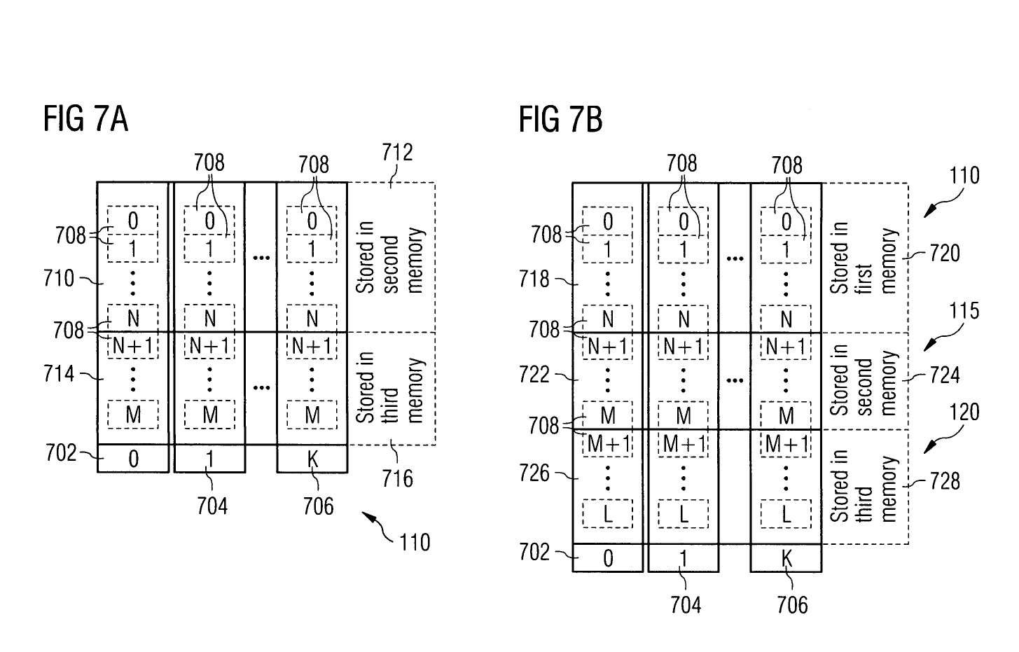

FIG. 7A is a diagram of the first memory cell field 110 of the memory system 100 of FIG. 4 illustrating the data partitioning in accordance with one embodiment of the invention. In this embodiment of the invention, the first memory cell field 110 serves as a write buffer. FIG. 7A shows a plurality of K (K being an arbitrary number greater than 0) data blocks (a first data block 702, a second data block 704, . . . , a K-th data block 706, which can be individually addressed. Each data block 702, 704, 706 includes M (M being an arbitrary number greater than 1) data elements, e.g., data bytes 708 (each data byte including eighth data bits). As is shown in FIG. 7A, the data bytes of each block are successively written into the first memory cell field 110 via the first serial to parallel converter 130 and the second serial to parallel converter 135. In other words, the first N+1 data bytes (data bytes 0 to N) of each block 702, 704, 706 are written into a first region 710 of the first memory cell field 110 from the first serial to parallel converter 130 and are then transferred to the second memory cell field 115 (symbolized in FIG. 7A by a block 712). Furthermore, the data bytes (N+1) to M are first written from the first serial to parallel converter 130 into the second serial to parallel converter 135 and then from the second serial to parallel converter 135 into a second region 714 of the first memory cell field 110. Then, the data bytes (N+1) to M are transferred to the third memory cell field 120 (symbolized in FIG. 4A by a block 716).

FIG. 7B is a diagram of the memory cell field 110, 115, 120 of the memory system 200 of FIG. 5 illustrating the data partitioning in accordance with another embodiment of the invention. In this embodiment of the invention, the first memory cell field 110 serves as a non-volatile memory as well. FIG. 7B shows a plurality of K (K being an arbitrary number greater than 0) data blocks (a first data block 702, a second data block 704, . . . , a K-th data block 706), which can be individually addressed. Each data block 702, 704, 706 includes L (L being an arbitrary number greater than 2) data elements, e.g., data bytes 708 (each data byte including eighth data bits). As is shown in FIG. 7B, the data bytes of each block are successively written into the first memory cell field 110 via the third serial to parallel converter 160, into the second memory cell field 115 via the third serial to parallel converter 160 and the first serial to parallel converter 130, and into the third memory cell field 120 via the third serial to parallel converter 160 and the second serial to parallel converter 135. In other words, the first N+1 data bytes (data bytes 0 to N) of each block 702, 704, 706 are written into a memory region 718 of the first memory cell field 110 from the third serial to parallel converter 160 and are then kept in the first memory cell field 110 in a non-volatile manner (symbolized in FIG. 7B by a block 720). Furthermore, the data bytes (N+1) to M are first written from the third serial to parallel converter 160 into the first serial to parallel converter 130 and then from the first serial to parallel converter 130 into a memory region 722 of the second memory cell field 120 (symbolized in FIG. 7B by a block 724). Further, the data bytes (M+1) to L are first written from the third serial to parallel converter 160 into the second serial to parallel converter 135 and then from the second serial to parallel converter 135 into a memory region 726 of the third memory cell field 120 (symbolized in FIG. 7B by a block 728).

The foregoing description has been presented for purposes of illustration and description. It is not intended to be exhaustive or to limit the invention to the precise form disclosed, and obviously many modifications and variations are possible in light of the disclosed teaching. The described embodiments were chosen in order to best explain the principles of the invention and its practical application to thereby enable others skilled in the art to best utilize the invention in various embodiments and with various modifications as are suited to the particular use contemplated. It is intended that the scope of the invention be defined by the claims appended hereto.

What is claimed is:

1. A memory system, comprising:
a plurality of resistive memory cell fields including at least a first resistive memory cell field and a second resistive memory cell field, the first resistive memory cell field formed with a plurality of resistive memory cells storing data at a first data storage speed, the second resistive memory cell field formed with a plurality of resistive memory cells storing data at a second data storage speed that is lower than the first data storage speed; and
a controller controlling data transfer between the plurality of resistive memory cell fields.

2. The memory system according to claim 1, wherein:
the first resistive memory cell field is volatile and serves as an input/output memory cell field; and
the second resistive memory cell field is non-volatile.

3. The memory system according to claim 1, wherein the plurality of resistive memory cells of the first resistive memory cell field provide an endurance at least 100 times greater than that of the plurality of resistive memory cells of the second resistive memory cell field.

4. The memory system according to claim 1, wherein the plurality of resistive memory cells of the first resistive memory cell field are programmed using a first programming current density, and the plurality of resistive memory cells of the second resistive memory cell field are programmed using a second programming current density, the second programming current density being higher than the first programming current density.

5. The memory system according to claim 1, wherein the plurality of resistive memory cells of the second resistive memory cell field comprise a plurality of multilevel memory cells.

6. The memory system according to claim 1, wherein the plurality of resistive memory cells of the first resistive memory cell field and the plurality of resistive memory cells of the second resistive memory cell field comprise the same type of resistive memory cells.

7. The memory system according to claim 6, wherein the plurality of resistive memory cells of the first resistive memory cell field and the plurality of resistive memory cells of the second resistive memory cell field comprise a plurality of reconfigurable conductive filament storage elements.

8. The memory system according to claim 7, wherein the plurality of reconfigurable conductive filament storage elements comprise a plurality of programmable metallization cells.

9. The memory system according to claim 1, wherein the first resistive memory cell field is formed with an architecture different than that of the second resistive memory cell field.

10. The memory system according to claim 1, wherein the first resistive memory cell field is formed with a transistor architecture and the second resistive memory cell field is formed with a diode architecture or a cross-point architecture.

11. The memory system according to claim 1, wherein the controller operates the first resistive memory cell field with a different operational mode than the second resistive memory cell field.

12. The memory system according to claim 1, further comprising a silicon die, wherein the controller and the plurality of resistive memory cell fields are both integrated on the silicon die.

13. The memory system according to claim 1, further comprising a plurality of silicon dies, wherein the controller and the plurality of resistive memory cell fields are integrated on different ones of the plurality of silicon dies.

14. The memory system according to claim 1, further comprising a plurality of silicon dies, wherein the plurality of resistive memory cell fields are integrated on different ones of the plurality of silicon dies.

15. The memory system according to claim 1, wherein the controller stores a unit of data in the first resistive memory cell field before storing the unit of data in the second resistive memory cell field.

16. The memory system according to claim 1, wherein the controller, when reading a unit of data, copies the unit of data from the second resistive memory cell field back into the first resistive memory cell field.

17. The memory system according to claim 1, wherein the controller copies a unit of data stored in the first resistive memory cell field into the second resistive memory cell field during at least one event selected from a group consisting of: a power loss, a system turn off, exceeding a predetermined filling value threshold for the first resistive memory cell field, and not using a predefined amount of data stored in the first resistive memory cell field for a predetermined amount of time.

18. The memory system according to claim 1, wherein:
the plurality of resistive memory cell fields includes a third resistive memory cell field; and
the controller copies a plurality of units of data stored in the second resistive memory cell field into the third resistive memory cell field before copying a plurality of units of data from the first resistive memory cell field into the second resistive memory cell field.

19. The memory system according to claim 1, wherein the plurality of resistive memory cell fields store a plurality of units of data associated with a plurality of data words, the plurality of data words at least indicating a number of access cycles since the plurality of units of data has been read or moved.

20. The memory system according to claim 19: wherein the plurality of data words indicate which of the plurality of units of data is permanently kept in the first resistive memory cell field while the first resistive memory cell field is supplied with power.

21. The memory system according to claim 1, wherein:
each resistive memory cell field of the plurality of resistive memory cell fields includes resistive multilevel memory cells storing a plurality of bits; and
except for a memory system I/O resistive memory cell field of the plurality of resistive memory cell fields, each one of the plurality of memory cell fields stores a number of bits that is greater than the number of bits being stored of memory cells of a memory cell field arranged upstream with regard to the memory system I/O resistive memory cell field.

22. The memory system according to claim 1, wherein one resistive memory cell field of the plurality of resistive memory cell fields comprises a memory system I/O resistive memory cell field, the I/O resistive memory cell field comprising volatile memory cells.

23. The memory system according to claim 1, further comprising:
an I/O port formed with a data bus width; and
a data bus width converter circuit;
wherein each one of the plurality of resistive memory cell fields is formed with a data bus width;
wherein the data bus width converter circuit adapts a data size from the data bus width of at least one of the plurality of resistive memory cell fields being read to the data bus width of the I/O port; and
wherein the controller controls data transfer between the plurality of resistive memory cell fields and the I/O port.

24. The memory system according to claim 23, wherein the data bus width of each one of the plurality of resistive memory cell fields is dependent on a speed of the one of the plurality of resistive memory cell fields.

25. A method of operating a memory system, the method comprising:
storing data in a plurality of resistive memory cells of a first resistive memory cell field of the memory system, the plurality of resistive memory cells of the first resistive memory cell field storing data at a first data storage speed; and
storing data in a plurality of resistive memory cells of a second resistive memory cell field of the memory system, the plurality of resistive memory cells of the second resistive memory cell field storing data at a second data storage speed that is lower than the first data storage speed.

26. The method according to claim 25, further comprising:
operating the plurality of resistive memory cells of the first resistive memory cell field to obtain an endurance at least 100 times greater than that of the plurality of resistive memory cells of the second resistive memory cell field.

27. The method according to claim 25, further comprising:
programming the plurality of resistive memory cells of the first resistive memory cell field using a first programming current density;
programming the plurality of resistive memory cells of the second resistive memory cell field using a second programming current density;
the second programming current density being higher than the first programming current density.

28. The method according to claim 25, further comprising:
operating the plurality of resistive memory cells of the second resistive memory cell field as a plurality of multilevel memory cells.

29. The method according to claim 25, further comprising:
operating the first resistive memory cell field using an operational mode different than an operational mode of the second resistive memory cell field.

30. The method according to claim 25, further comprising:
storing data in the first resistive memory cell field and copying the data from the first resistive memory cell field into the second resistive memory cell field.

31. The method according to claim 25, further comprising reading the data such that when the data is read, the data is copied from the second resistive memory cell field back into the first resistive memory cell field.

32. The method according to claim 25, further comprising:
copying data stored in the first resistive memory cell field into the second resistive memory cell field during a predetermined event.

33. The method according to claim 25, further comprising:
copying data stored in the first resistive memory cell field into the second resistive memory cell field during at least one event selected from a group of events consisting of:
a power loss;
a system turn off;
exceeding a predetermined filling value threshold for the first resistive memory cell field; and
not using a predefined amount of data stored in the first resistive memory cell field for a predetermined amount of time.

34. The method according to claim 25, further comprising:
copying data stored in the second resistive memory cell field into a third resistive memory cell field of the memory system before transferring data from the first resistive memory cell field into the second resistive memory cell field.

35. The method according to claim 25, further comprising:
concurrently initiating a read access of more than one of the plurality of resistive memory cell fields.

36. A memory system, comprising:
a volatile resistive memory cell field formed with a plurality of resistive memory cells storing data at a first data storage speed;
a plurality of non-volatile resistive memory cell fields, each of the plurality of non-volatile resistive memory cell fields formed with a plurality of resistive memory cells storing data at a second data storage speed lower than the first data storage speed; and
a controller storing data in the volatile resistive memory cell field and copying the data from the volatile resistive memory cell field to a first one of the plurality of non-volatile resistive memory cell fields.

37. The memory system according to claim 36, wherein the controller copies the data from the first one of the plurality of non-volatile resistive memory cell fields to a second one of the plurality of non-volatile resistive memory cell fields.

38. The memory system according to claim 36, wherein the controller programs the plurality of resistive memory cells of the volatile resistive memory cell field differently than the plurality of resistive memory cells of each of the plurality of non-volatile resistive memory cell fields.

39. The memory system according to claim 36, wherein the controller programs the plurality of resistive memory cells of the volatile resistive memory cell field using a first programming current density and programs the plurality of resistive memory cells of each of the plurality of non-volatile resistive memory cell fields using a second programming current density, the second programming current density being higher than the first programming current density.

40. The memory system according to claim 36, wherein the plurality of resistive memory cells of at least some of the plurality of non-volatile resistive memory cell fields comprise a plurality of multilevel memory cells.

41. The memory system according to claim 36, wherein the volatile resistive memory cell field is formed with an architecture that is different than an architecture of at least some of the plurality of non-volatile resistive memory cell fields.

42. A method of operating a memory system, the method comprising:
storing data in a plurality of resistive memory cells of a volatile resistive memory cell field storing data at a first data storage speed; and
copying the data from the plurality of resistive memory cells of the volatile resistive memory cell field to a plurality of resistive memory cells of a non-volatile resistive memory cell field storing data at a second data storage speed that is lower than the first data storage speed.

43. The method according to claim 42, further comprising:
copying the data from the plurality of resistive memory cells of the non-volatile resistive memory cell field to a plurality of resistive memory cells of another non-volatile resistive memory cell field providing a storage density greater than a first storage density of the volatile resistive memory cell field and greater than a second storage density of the non-volatile resistive memory cell field.

44. A memory system, comprising:
a plurality of resistive memory cell fields including at least a first resistive memory cell field and a second resistive memory cell field, the first resistive memory cell field formed with a plurality of resistive memory cells storing data at a first data storage speed, the second resistive memory cell field formed with a plurality of resistive memory cells storing data at a second data storage speed that is lower than the first data storage speed; and
a controller controlling data transfer between the plurality of resistive memory cell fields;
wherein the plurality of resistive memory cells of the first resistive memory cell field are programmed using a first programming current density, and the plurality of resistive memory cells of the second resistive memory cell field are programmed using a second programming current density, the second programming current density being higher than the first programming current density.

45. A memory system, comprising:
a plurality of resistive memory cell fields including at least a first resistive memory cell field and a second resistive memory cell field, the first resistive memory cell field formed with a plurality of resistive memory cells storing data at a first data storage speed, the second resistive memory cell field formed with a plurality of resistive memory cells storing data at a second data storage speed that is lower than the first data storage speed, the first resistive memory cell field formed with an architecture different than that of the second resistive memory cell field; and
a controller controlling data transfer between the plurality of resistive memory cell fields.

46. A memory system, comprising:
a plurality of memory cell fields including at least a first memory cell field and a second memory cell field, the first memory cell field formed with a plurality of memory cells storing data at a first data storage speed, the second memory cell field formed with a plurality of memory cells storing data at a second data storage speed lower than the first data storage speed;
the memory cells of the first memory cell field and the memory cells of the second memory cell field being memory cells of the same memory cell type; and
a controller controlling data transfer between the plurality of memory cell fields.
